(19) United States
(12) Patent Application Publication
(10) Pub. No.: US 2025/0237949 A1
(43) Pub. Date: Jul. 24, 2025

(54) RESIST COMPOSITION, METHOD FOR MANUFACTURING RESIST FILM, AND METHOD FOR MANUFACTURING DEVICE

(71) Applicant: Merck Patent GMBH, Darmstadt (DE)

(72) Inventors: Tetsumasa Takaichi, Shizuoka (JP); Yuki Yoshida, Shizuoka (JP)

(21) Appl. No.: 19/080,117

(22) Filed: Mar. 14, 2025

Related U.S. Application Data
(63) Continuation of application No. PCT/EP2023/075214, filed on Sep. 14, 2023.

(30) Foreign Application Priority Data
Sep. 16, 2022 (JP) 2022-148453

(51) Int. Cl. G03F 7/039; G03F 7/004; G03F 7/16; G03F 7/38

(52) U.S. Cl. CPC G03F 7/0392; G03F 7/0045; G03F 7/168; G03F 7/38

(57) ABSTRACT

Provided are a resist composition, a method for manufacturing a resist film, and a method for manufacturing a device.

### CROSS-REFERENCE TO RELATED APPLICATIONS

The present application is a Continuation Application of International Application No. PCT/EP2023/075214, filed Sep. 14, 2023, which claims the benefit of priority of JP Application No. 2022-148453, filed Sep. 16, 2022, the entire contents of each of which is incorporated herein by reference.

### FIELD OF THE INVENTION

The present invention relates to a resist composition, a method for manufacturing a resist film, and a method for manufacturing a device.

### BACKGROUND ART

In recent years, needs for high integration of LSI has been increasing, and refinement of patterns is required. In order to respond such needs, lithography processes using KrF excimer laser (248 nm), ArF excimer laser (193 nm), extreme ultraviolet (EUV; 13 nm), X-ray of short wavelength, electron beam or the like have been put to practical use. In order to respond to such refinement of resist patterns, also for photosensitive resin compositions to be used as a resist during refinement processing, those having high resolution are required. Finer patterns can be formed by exposing with light of a short wavelength, but high dimensional accuracy is required.

In the lithography process, a resist pattern is formed by exposing and developing the resist. The phenomenon in which at the time of exposure, the incident light on the resist and the reflected light from the substrate or the air interface interfere with each other to generate standing wave is known. The generation of standing wave reduces the pattern dimensional accuracy. Attempts have been made to form an anti-reflective coating on the top layer and/or bottom layer of the resist to reduce standing wave.

It has been proposed that, by containing an organic compound in a lithography component such as a resist, for example, a moving speed of an acid generated by an acid generator is suppressed, and standing wave is reduced (WO 2022/023230 A).

### PRIOR ART DOCUMENTS

### Patent Documents

[Patent document 1] WO 2022/023230 A

### BRIEF DESCRIPTION OF THE DRAWINGS

FIG. 1 is a conceptual diagram illustrating a cross-sectional shape of a resist pattern when not affected by standing wave and when affected by standing wave; and

FIG. 2 is a conceptual diagram illustrating a cross-sectional shape of a trench pattern.

### SUMMARY OF THE INVENTION

### Problems to be Solved by the Invention

The present inventors have considered that there are one or more objectives that still need improvements in the resist composition. These problems are, for example, as follows.

A side wall of the resist pattern swings due to the influence of standing wave; a resist pattern width is non-uniform; the rectangularity of the resist pattern is low; sensitivity is low; and resolution is low.

### Means for Solving the Problems

A resist composition according to the present inventors contains a polymer (A), a photoacid generator (B), and an amide compound (D).

The amide compound (D) is represented by Formula (D-1),

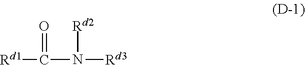

where,
R^{d1} is linear C₁₋₁₀ alkyl, branched C₃₋₁₀ alkyl or —NR^{d4}R^{d5},
R^{d2} and R^{d3} are each independently hydrogen, linear C₁₋₁₀ alkyl or branched C₃₋₁₀ alkyl,
R^{d4} and R^{d5} are each independently hydrogen, linear C₁₋₁₀ alkyl or branched C₃₋₁₀ alkyl,
where, when R^{d1} is alkyl, R^{d1} may form a ring with R^{d2}, and when R^{d1} is —NR^{d4}R^{d5}, R^{d4} or R^{d5} may form a ring with R^{d2}, and
when R^{d1}, R^{d2}, R^{d3}, R^{d4} and/or R^{d5} is alkyl, methylene (—CH₂—) in the alkyl may be replaced with —NH—, —S— or —O—.

A method for manufacturing a resist film according to the present invention includes steps below:
applying the above-described composition onto a substrate; and
heating the composition to form a resist film.

A method for manufacturing a device according to the present invention includes the above-described method.

### Effects of the Invention

According to the present invention, it is possible to expect one or more of the following effects.

The effect of reducing standing wave in the resist pattern is high; the resist pattern width is uniform; the rectangularity of the resist pattern is high; the resolution of the resist pattern is high; the heat resistance of the resist pattern is high; and the efficiency of the manufacturing process is high.

### MODE FOR CARRYING OUT THE INVENTION

Embodiments of the present invention are described below in detail.

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

And/or includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plurality of types of repeating units, these repeating units copolymerize. These copolymerization are any of alternating copolymerization, random copolymerization, block copolymerization, graft copolymerization or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as a solvent (F) or another component.

### Resist Composition

A resist composition according to the present invention (hereinafter, referred to as the composition) contains a polymer (A), a photoacid generator (B), and an amide compound (D) having a particular structure.

The composition according to the present invention is preferably a chemically amplified resist composition, and more preferably a chemically amplified KrF resist composition.

The composition according to the present invention can also be used for both a positive type and a negative type. In a preferred embodiment of the present invention, the composition according to the present invention is a positive type chemically amplified resist composition, and more preferably a positive type chemically amplified KrF resist composition.

### Polymer (A)

The composition according to the present invention contains a polymer (A) (hereinafter, referred to as the component (A); the same applies to other components). The polymer (A) is preferably a polymer having a reactive group, and more preferably an alkali-soluble polymer.

The polymer (A) includes at least one of repeating units represented by Formulae (A-1) and (A-2), and preferably, further includes at least one of repeating units represented by Formulae (A-3) and (A-4). More preferably, the polymer (A) includes the repeating unit represented by Formula (A-1), and further includes at least one of the repeating units represented by Formulae (A-3) and (A-4). In a preferred embodiment, the polymer (A) includes the repeating units represented by Formulae (A-1), (A-2), and (A-3), and more preferably substantially consists of the repeating units represented by Formulae (A-1), (A-2), and (A-3).

Formula (A-1) is as follows:

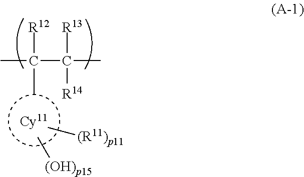

where,
C_{y}¹¹ is each independently aryl or heteroaryl having 5 or 6 ring atoms, preferably benzene.
R¹¹ is each independently C₁₋₅ alkyl (wherein methylene in the alkyl can be replaced with oxy), preferably methyl or ethyl, more preferably methyl. In the present invention, the expression “methylene in the alkyl can be replaced with oxy” means that oxy can be present between carbon atoms in the alkyl, and it is not intended that the terminal carbon in the alkyl becomes oxy, i.e., it is not intended to have alkoxy or hydroxy.
R¹², R¹³, and R¹⁴ are each independently hydrogen, C₁₋₅ alkyl, C₁₋₅ alkoxy or —COOH, preferably hydrogen or methyl, more preferably hydrogen.
p11 is 0 to 4, preferably 0 or 1, more preferably 0.
p15 is 1 to 2, preferably 1. Provided that, p11+p15≤5 is satisfied.

The polymer (A) can include a plurality of types of repeating units represented by Formula (A-1). For example, it is possible for the polymer (A) to have a structural unit of p15=1 and a structural unit of p15=2 at a ratio of 1:1. In this case, it becomes p15=1.5 as a whole. Hereinafter, unless otherwise specified, the same applies to the numbers for representing polymer in the present invention.

Exemplified embodiments of Formula (A-1) includes the following:

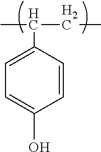

Formula (A-2) is as follows:

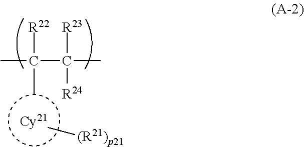

where,
C_{y}²¹ is each independently aryl or heteroaryl having 5 or 6 ring atoms, preferably benzene.
R²¹ is each independently C₁₋₅ alkyl (where methylene in the alkyl may be replaced with oxy), preferably methyl, ethyl, t-butyl or t-butoxy, more preferably methyl or ethyl, further preferably methyl.
R²², R²³ and R²⁴ are each independently hydrogen, C₁₋₅ alkyl, C₁₋₅ alkoxy or —COOH, preferably hydrogen or methyl, more preferably hydrogen.
p21 is 0 to 5, preferably 0, 1, 2, 3, 4 or 5, more preferably 0 or 1, further preferably 0.

Exemplified embodiments of Formula (A-2) includes the following:

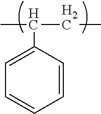

Formula (A-3) is as follows:

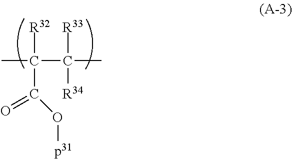

where,
R³², R³³, and R³⁴ are each independently hydrogen, C₁₋₅ alkyl, C₁₋₅ alkoxy or —COOH; preferably hydrogen, methyl, ethyl, t-butyl, methoxy, t-butoxy or —COOH; more preferably hydrogen or methyl; further preferably hydrogen.
P³¹ is C₄₋₂₀ alkyl. Some or all of alkyl can form a ring, some or all of H of the alkyl can be substituted with halogen, and methylene in the alkyl can be replaced with oxy or carbonyl. The alkyl moiety of P³¹ is preferably branched or cyclic. When the C₄₋₂₀ alkyl in P³¹ is replaced with halogen, it is preferable that all are replaced, and the halogen that replaces is preferably F or Cl, more preferably F. It is a preferred embodiment of the present invention that H of the C₄₋₂₀ alkyl in P³¹ is not replaced with any halogen. P³¹ is preferably methyl, isopropyl, t-butyl, cyclopentyl, methylcyclopentyl, ethylcyclopentyl, cyclohexyl, methylcyclohexyl, ethylcyclohexyl, adamantyl, methyladamantyl or ethyladamantyl, more preferably t-butyl, ethylcyclopentyl, ethylcyclohexyl or ethyladamantyl, further preferably t-butyl, ethylcyclopentyl or ethyladamantyl, further more preferably t-butyl.

Exemplified embodiments of Formula (A-3) include the following:

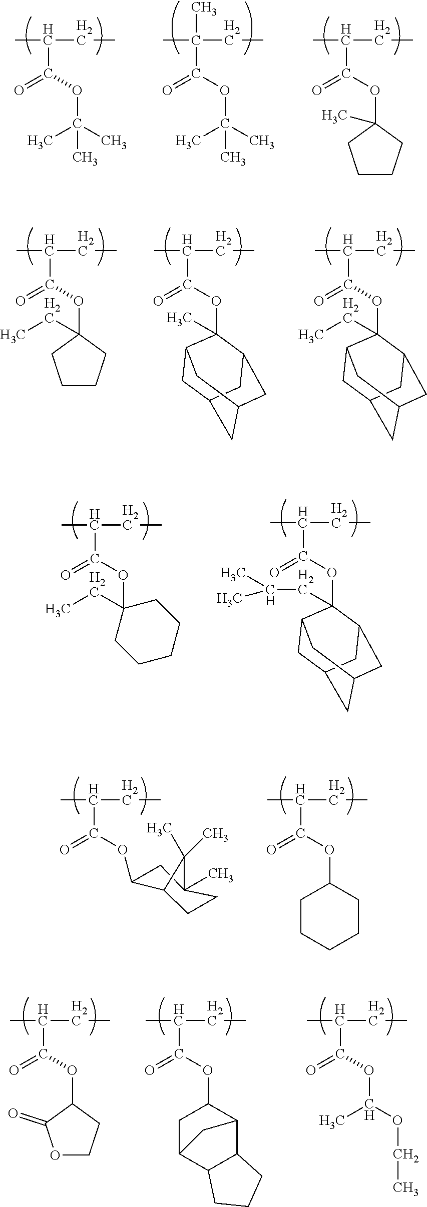

Formula (A-4) is as follows:

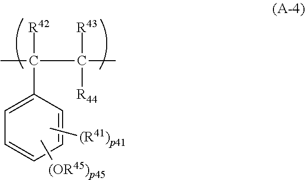

where,
R⁴¹ is each independently C₁₋₅ alkyl (where methylene in the alkyl may be replaced with oxy), preferably methyl, ethyl or t-butyl, more preferably methyl.
R⁴⁵ is each independently C₁₋₅ alkyl (wherein methylene in the alkyl can be replaced with oxy), preferably methyl, t-butyl or —CH(CH₃)—O—CH₂CH₃.
R⁴², R⁴³, and R⁴⁴ are each independently hydrogen, C₁₋₅ alkyl, C₁₋₅ alkoxy or —COOH, preferably hydrogen or methyl, more preferably hydrogen.
p41 is 0 to 4, more preferably 0 or 1, further preferably 0.
p45 is 1 to 2, more preferably 1.
p41+p45≤5 is satisfied.

Exemplified embodiments of Formula (A-4) include the following:

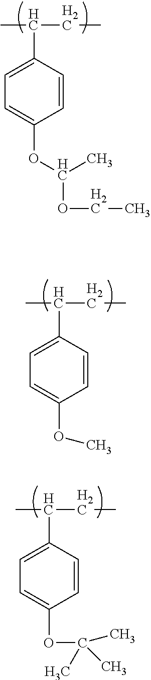

n_{A-1}, n_{A-2}, n_{A-3} and n_{A-4}, which are the numbers of repeating units, of the repeating units (A-1), (A-2), (A-3), and (A-4) in the polymer (A) will be described below.
n_{A-1}/(n_{A-1}+n_{A-2}+n_{A-3}+n_{A-4}) is preferably 0 to 100%, more preferably 50 to 80%, further preferably 55 to 75%, and further more preferably 55 to 65%.
n_{A-2}/(n_{A-1}+n_{A-2}+n_{A-3}+n_{A-4}) is preferably 0 to 100%, more preferably 0 to 30%, further preferably 5 to 25%, and further more preferably 15 to 25%.
n_{A-3}/(n_{A-1}+n_{A-2}+n_{A-3}+n_{A-4}) is preferably 0 to 50%, more preferably 10 to 40%, further preferably 15 to 35%, and further more preferably 15 to 25%.
n_{A-4}/(n_{A-1}+n_{A-2}+n_{A-3}+n_{A-4}) is preferably 0 to 50%, more preferably 0 to 30%, further preferably 0 to 10%, and further more preferably 0 to 5%. It is also a preferred embodiment of the present invention that n_{A-4} is 0.

A preferred embodiment includes the following: n_{A-1}/(n_{A-1}+n_{A-2}+n_{A-3}+n_{A-4})=40 to 80%, n_{A-2}/(n_{A-1}+n_{A-2}+n_{A-3}+n_{A-4})=0 to 40%, n_{A-3}/(n_{A-1}+n_{A-2}+n_{A-3}+n_{A-4})=10 to 50%, and n_{A-4}/(n_{A-1}+n_{A-2}+n_{A-3}+n_{A-4})=0 to 40%.

The polymer (A) can also include an additional repeating unit other than the repeating units represented by Formulae (A-1), (A-2), (A-3) and (A-4). When the total number of all repeating units included in the polymer (A) is designated as nₜₒₜₐₗ, (n_{A-1}+n_{A-2}+n_{A-3}+n_{A-4})/nₜₒₜₐₗ is preferably 80 to 100%, more preferably 90 to 100%, and further preferably 95 to 100%. It is also a preferred embodiment of the polymer (A) to include no further repeating unit.

When the composition according to the present invention is a positive type resist composition, exemplified embodiments of the polymer (A) include the following:

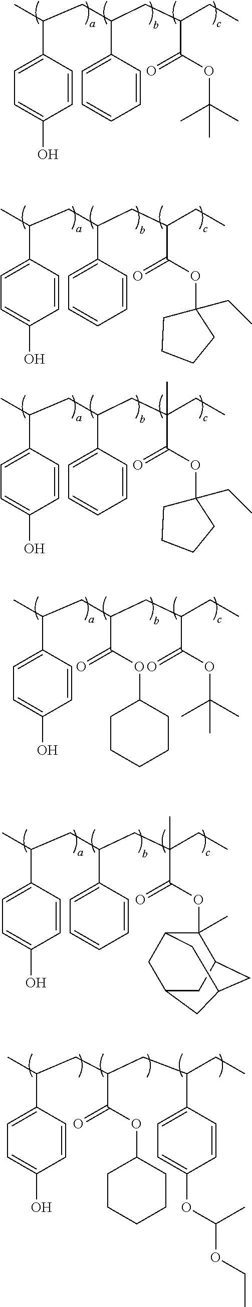

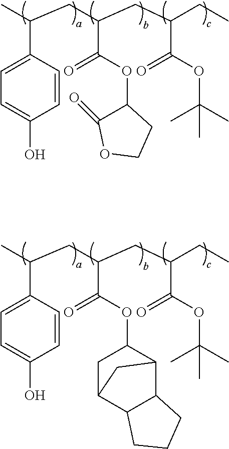

When the composition according to the present invention is a negative type resist composition, exemplified embodiments of the polymer (A) include the following:

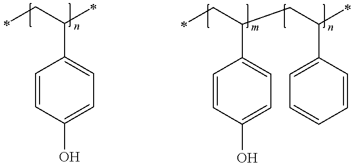

A mass average molecular weight (hereinafter, referred to as Mw) of the polymer (A) is 3,000 to 50,000, more preferably 4,000 to 20,000, further preferably 10,000 to 19,000, and further more preferably 11,000 to 13,000. Without wishing to be bound by theory, it is thought that due to the polymer (A) having this Mw, it becomes possible to form a resist pattern with good rectangularity or resolution from the composition of the present invention.

In the present invention, Mw can be measured by gel permeation chromatography (GPC). In the measurement, it is a preferable example that a GPC column at 40 degrees Celsius, an elution solvent of tetrahydrofuran at 0.6 mL/min and monodisperse polystyrene as a standard are used.

The content of the polymer (A) is preferably 10 to 60 mass %, more preferably 10 to 30 mass %, and further preferably 12 to 18 mass %, based on the total mass of the composition.

The composition according to the present invention may contain a polymer other than the polymer (A), but an embodiment in which no polymer other than the polymer (A) is one preferred embodiment.

### Photoacid Generator (B)

The composition according to the present invention contains a photoacid generator (B). The photoacid generator (B) releases an acid by light irradiation, and the acid acts on the polymer to play a role of increasing the solubility of the polymer in an alkaline aqueous solution. For example, when the polymer has an acid group protected by a protecting group, the protecting group is eliminated by the acid. The component (B) used in the composition according to the present invention can be selected from conventionally known ones.

The photoacid generator (B) preferably releases an acid with an acid dissociation constant pKa (H₂O) of −20 to 1.4 by exposure, and releases an acid with an acid dissociation constant pKa (H₂O) of more preferably −16 to 1.4, further preferably −16 to 1.2, and further more preferably −16 to 1.1.

The photoacid generator (B) is preferably represented by Formula (B-1).

Bⁿ⁺ cation Bⁿ⁻ anion (B-1)
where,
Bⁿ⁺ cation consists of at least one cation selected from the group consisting of cations represented by Formulae (BC1) to (BC3), and is n-valent (where, n is 1 to 3, preferably 1 or 2, and more preferably 1) as a whole.
Bⁿ⁻ anion consists of at least one anion selected from the group consisting of anions represented by Formulae (BA1) to (BA4), and is n-valent as a whole.

Formula (BC1) is as follows:

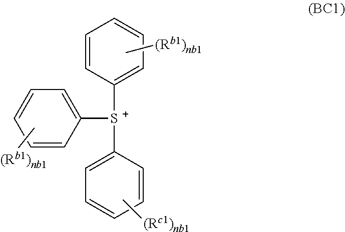

where,
R^{b1} is each independently C₁₋₆ alkyl, C₁₋₆ alkoxy, C₆₋₁₂ aryl, C₆₋₁₂ arylthio, C₆₋₁₂ aryloxy, nitro, sulfo, carboxy, hydroxy, amino, cyano, halogen, C₁₋₆ halogen-substituted alkyl or a C₂₋₈ hydrocarbon group having an ester bond, preferably C₁₋₆ alkyl, C₁₋₆ alkoxy, C₆₋₁₂ aryl, C₆₋₁₂ arylthio or C₆₋₁₂ aryloxy, more preferably methyl, ethyl, t-butyl, methoxy, ethoxy, phenylthio or phenyloxy, and further preferably t-butyl, methoxy, ethoxy, phenylthio or phenyloxy.
nb1 is each independently 0, 1, 2 or 3, preferably 0 or 1.

In a preferred embodiment, all nb1's are 0.

In another preferred embodiment, all nb1's are 1, and all R^{b1}'s are identical.

Exemplified embodiments of Formula (BC1) include the following:

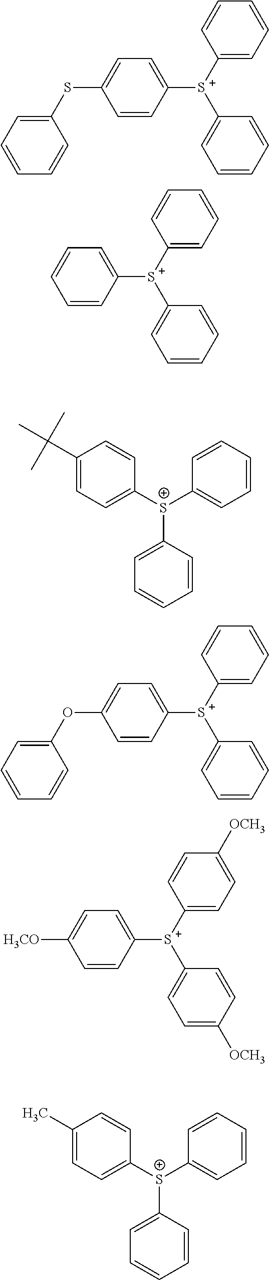 [SMILES: c1ccc(Sc2ccc([S+](c3ccccc3)c3ccccc3)cc2)cc1 ; c1ccc([S+](c2ccccc2)c2ccccc2)cc1 ; CC(C)(C)c1ccc([S+](c2ccccc2)c2ccccc2)cc1 ; c1ccc(Oc2ccc([S+](c3ccccc3)c3ccccc3)cc2)cc1 ; COc1ccc([S+](c2ccc(OC)cc2)c2ccc(OC)cc2)cc1 ; Cc1ccc([S+](c2ccccc2)c2ccccc2)cc1]

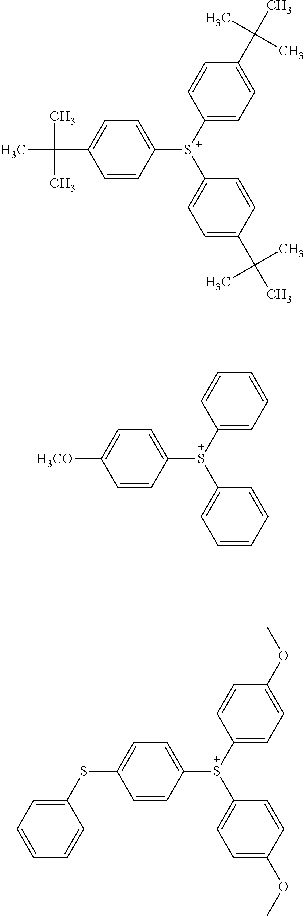 [SMILES: CC(C)(C)c1ccc([S+](c2ccc(C(C)(C)C)cc2)c2ccc(C(C)(C)C)cc2)cc1 ; COc1ccc([S+](c2ccccc2)c2ccccc2)cc1 ; COc1ccc([S+](c2ccc(OC)cc2)c2ccc(Sc3ccccc3)cc2)cc1]

Formula (BC2) is as follows:

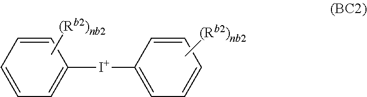

where,
R^{b2} is each independently C₁₋₆ alkyl, C₁₋₆ alkoxy, C₆₋₁₂ aryl, nitro, sulfo, carboxy, hydroxy, amino, halogen, C₁₋₆ halogen-substituted alkyl or a C₂₋₈ hydrocarbon group having an ester bond, preferably C₁₋₆ alkyl, C₁₋₆ alkoxy or C₆₋₁₂ aryl, more preferably alkyl having a C₄₋₆ branched structure, further preferably t-butyl or 1,1-dimethylpropyl, and further more preferably t-butyl.
nb2 is each independently 0, 1, 2 or 3, preferably each 1.

Exemplified embodiments of Formula (BC2) include the following:

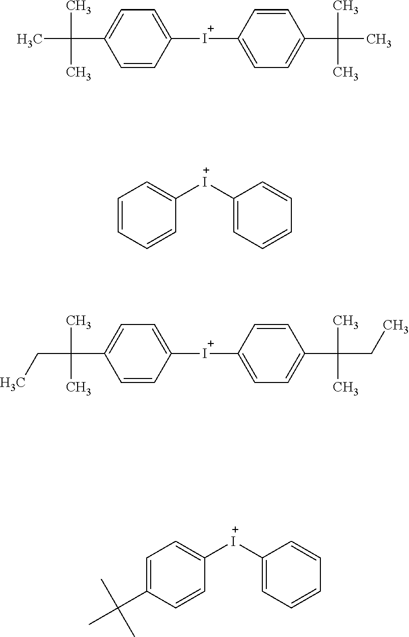

Formula (BC3) is as follows:

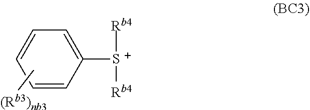

where,
R^{b3} is each independently C₁₋₆ alkyl, C₁₋₆ alkoxy, C₆₋₁₂ aryl, nitro, sulfo, carboxy, hydroxy, amino, halogen, C₁₋₆ halogen-substituted alkyl or a C₂₋₈ hydrocarbon group having an ester bond, preferably, C₁₋₆ alkyl, C₁₋₆ alkoxy or C₆₋₁₂ aryl, preferably, methyl, ethyl, methoxy or ethoxy, more preferably methyl or methoxy.
R^{b4} is each independently C₁₋₆ alkyl, preferably methyl or ethyl, more preferably methyl. Provided that, two R^{b4} may be linked to each other to form a ring, but preferably do not form a ring.
nb3 is each independently 0, 1, 2 or 3, more preferably 3.

Exemplified embodiments of Formula (BC3) include the following:

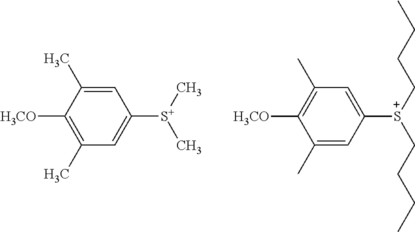 [SMILES: COc1c(C)cc([S+](C)C)cc1C ; CCCC[S+](CCCC)c1cc(C)c(OC)c(C)c1]

Bⁿ⁺ cation is preferably selected from the group consisting of a cation represented by Formula (BC1) or (BC2), and more preferably a cation represented by Formula (BC1).

Formula (BA1) is as follows:

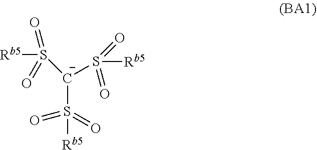

where,
R^{b5} is each independently C₁₋₆ fluorine-substituted alkyl, C₁₋₆ fluorine-substituted alkoxy or C₁₋₆ alkyl. For example, —CF₃ means one in which hydrogen of methyl (C₁) is replaced with fluorine. Preferably, all of the hydrogens present in the C₁₋₆ fluorine-substituted alkyl is replaced with fluorine. The alkyl moiety of R^{b5} is preferably methyl, ethyl or t-butyl (more preferably methyl). In a suitable embodiment, R^{b5} is preferably fluorine-substituted alkyl more preferably —CF₃.

Exemplified embodiments of Formula (BA1) include the following:

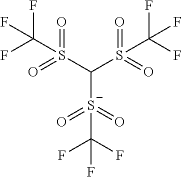

Formula (BA2) is as follows:

R^{b6}—SO₂⁻ (BA2)
where,
R^{b6} is C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, preferably C₁₋₆ fluorine-substituted alkyl, and more preferably C₂₋₆ fluorine-substituted alkyl. The alkyl moiety of R^{b6} is suitably methyl, ethyl, propyl, butyl or pentyl, more suitably propyl, butyl or pentyl, and further suitably butyl. The alkyl moiety of R^{b6} is preferably linear. R^{b6} is suitably C₁₋₆ fluorine-substituted alkyl.

Exemplified embodiments of Formula (BA2) include the following: C₄F₉SO₃⁻ and C₃F₇SO₃⁻

Formula (BA3) is as follows:

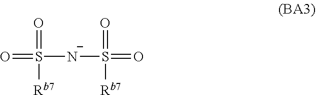

where,
R^{b7} is each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, and preferably C₂₋₆ fluorine-substituted alkyl. The alkyl moiety of R^{b7} is preferably methyl, ethyl, propyl, butyl or pentyl, more preferably methyl, ethyl or butyl, further preferably butyl. The alkyl moiety of R^{b7} is preferably linear.
where, two R^{b7} may be bonded to each other to form fluorine-substituted heterocyclic structure, and in this case, the heterocyclic ring may be a monocyclic ring or a polycyclic ring, but is preferably a monocyclic ring structure having 5 to 8 members.

Exemplified embodiments of Formula (BA3) include the following:

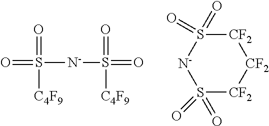

Formula (BA4) is as follows:

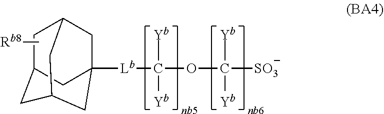

where,
R^{b8} is hydrogen, C₁₋₆ alkyl, C₁₋₆ alkoxy or hydroxy, preferably hydrogen, methyl, ethyl, methoxy or hydroxy, and more preferably hydrogen or hydroxy.
L^{b} is carbonyl, oxy or carbonyloxy, preferably carbonyl or carbonyloxy, and more preferably carbonyl.
Y^{b} is each independently hydrogen or fluorine, and preferably, at least one or more thereof is fluorine.
nb5 is an integer of 0 to 10, preferably 0.
nb6 is an integer of 0 to 21, preferably 4, 5 or 6.

Exemplified embodiments of Formula (BA4) include the following:

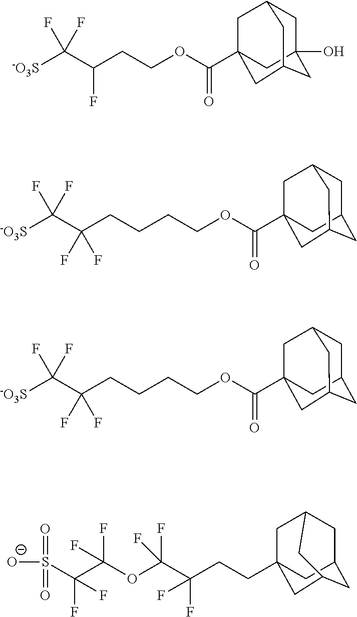

A molecular weight of the component (B) is preferably 400 to 2,500 and more preferably 400 to 1,500.

The component (B) may be one or two or more kinds, but is preferably one or two or more kinds, and more preferably one kind.

The content of the component (B) is preferably 0.05 to 5 mass %, more preferably 0.1 to 5 mass %, further preferably 1 to 4 mass %, based on the polymer (A).

### Photoreaction Quencher (C)

The composition according to the present invention can further contain a photoreaction quencher (C). The photoreaction quencher (C) releases an acid by light irradiation, but the acid does not act directly on the polymer. In this respect, the photoreaction quencher is different from the photoacid generator (B) having a direct action on the polymer by eliminating the protecting group of the polymer by the released acid.

The component (C) functions as a quencher that suppresses diffusion of an acid derived from the component (B) elimination generated in the exposed region. This is not bound by theory, but is considered to be the following mechanism. By exposure, an acid is released from the component (B), and when this acid diffuses into an unexposed region (a region not exposed), salt exchange occurs with the component (C). That is, the anion of the component (B) and the cation of the component (C) become salts. This suppresses the diffusion of the acid. At this time, the anion of the component (C) is released, but this is a weak acid and cannot deprotect the polymer, so that it is considered that the unexposed region is not affected.

The photoreaction quencher (C) releases an acid with an acid dissociation constant pKa (H₂O) of preferably 1.5 to 8, more preferably 1.5 to 5 by exposure.

The component (C) is preferably at least one selected from the group consisting of photoreaction quenchers represented by Formula (C-1).
C^{m+} cation C^{m-} anion Formula (C-1)
where,
C^{m+} cation consists of at least one cation selected from the group consisting of cations represented by Formulae (CC1) and (CC2), and is m-valent (where, m is 1 to 3) as a whole.
C^{m-} anion consists of at least one anion represented by Formula (CA) and is m-valent as a whole.

The m-valent is preferably monovalent or divalent, and more preferably monovalent.

Formula (CC1) is as follows:

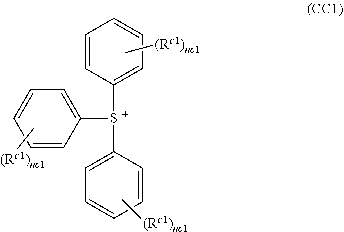

where,
R¹ is each independently C₁₋₆ alkyl, C₁₋₆ alkoxy or C₆₋₁₂ aryl, preferably methyl, ethyl, t-butyl, methoxy, ethoxy, phenylthio or phenyloxy, more preferably t-butyl, methoxy, ethoxy, phenylthio or phenyloxy, and further preferably t-butyl or methoxy.
nc1 is each independently 0, 1, 2 or 3, more preferably 0 or 1.

In a preferred embodiment, all nc1's are 0.

In another preferred embodiment, all nc1 's are 1, and all R^{c1}'s are identical.

Exemplified embodiments of Formula (CC1) include the following:

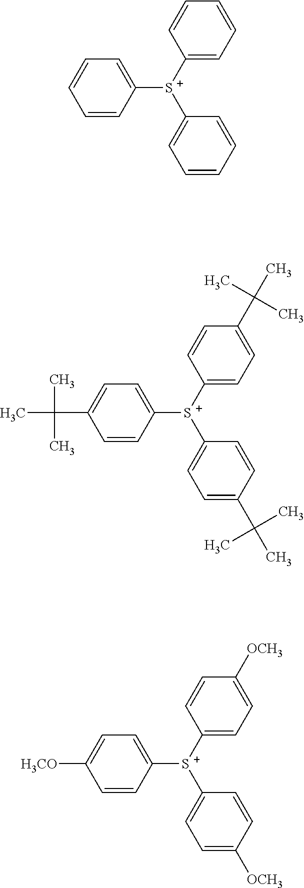 [SMILES: c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; COc1ccc([S+](c2ccc(OC)cc2)c2ccc(OC)cc2)cc1]

Formula (CC2) is as follows:

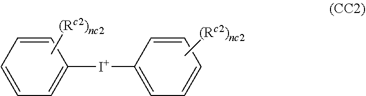

where,
R_{c2} is each independently C₁₋₆ alkyl, C₁₋₆ alkoxy or C₆₋₁₂ aryl, and preferably, R^{c2}, which is alkyl having a C₄₋₆ branched structure, may be the same or different, and is more preferably the same. R^{c2} is further preferably t-butyl or 1,1-dimethylpropyl, further more preferably t-butyl.
nc2 is each independently 0, 1, 2 or 3, preferably each 1.

Exemplified embodiments of Formula (CC2) include the following:

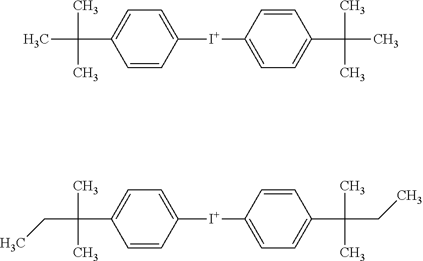

Formula (CA) is as follows:

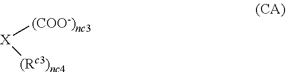

where,
X is C₁₋₂₀ hydrocarbon or C₆₋₁₂ aryl. X may be linear, branched or cyclic, but is preferably linear or cyclic. When X is linear, X is preferably C₁₋₄ (more preferably C₁₋₂), has one double bond in the chain, but is preferably saturated. When X is cyclic, X may be a monocyclic ring of an aromatic ring or a saturated monocyclic ring or polycyclic ring, in the case of a monocyclic ring, a 6-membered ring is preferable, and in the case of a polycyclic ring, an adamantane ring is preferable. X is preferably methyl, ethyl, propyl, butyl, ethane, phenyl, cyclohexane or adamantane, more preferably methyl, phenyl or cyclohexane, and further preferably phenyl.
R^{c3} is each independently hydroxy, carboxy, C₁₋₆ alkyl or C₆₋₁₀ aryl, preferably hydroxy, methyl, ethyl, 1-propyl, 2-propyl, t-butyl or phenyl, and more preferably hydroxy.
nc3 is 1, 2 or 3, preferably 1 or 2, and more preferably 1.
nc4 is 0, 1 or 2, preferably 0 or 1, and more preferably 1.

Exemplified embodiments of Formula (CA) include the following:

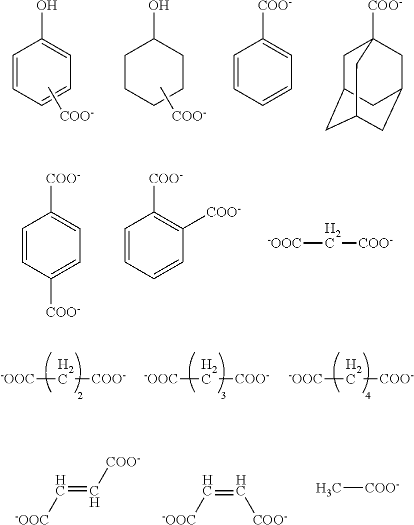

A molecular weight of the photoreaction quencher (C) is preferably 300 to 1,400 and more preferably 300 to 1,200.

The content of the photoreaction quencher (C) is preferably 0.01 to 3 mass %, more preferably 0.05 to 1.5 mass %, and further preferably 0.08 to 0.8 mass %, based on the total mass of the polymer (A).

### Amide Compound (D)

The composition according to the present invention contains an amide compound (D). The component (D) is represented by Formula (D), and does not contain anilide or imide.

In the present invention, by containing the amide compound (D), the influence of the standing wave can be remarkably suppressed. Without being bound by theory, it is considered that the component (D) has an amide structure, and the structure easily interacts with the acid generated from the photoacid generator (B), so that the transfer rate of the acid is suppressed.

Formula (D-1) is as follows:

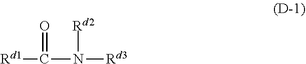

where,
R^{d1} is linear C₁₋₁₀ alkyl, branched C₃₋₁₀ alkyl or —NR^{d4}R^{d5},
R^{d2} and R^{d3} are each independently hydrogen, linear C₁₋₁₀ alkyl or branched C₃₋₁₀ alkyl,
R^{d4} and R^{d5} are each independently hydrogen, linear C₁₋₁₀ alkyl or branched C₃₋₁₀ alkyl,
where, when R^{d1} is alkyl, R^{d1} may form a ring with R^{d2}, and when R^{d1} is —NR^{d4}R^{d5}, R^{d4} or R^{d5} may form a ring with R^{d2}, and
when R^{d1}, R^{d2}, R^{d3}, R^{d4} and/or R^{d5} is alkyl, methylene (—CH₂—) in the alkyl may be replaced with —NH—, —S— or —O—.

The amide compound (D) is preferably represented by Formula (D-1a) or Formula (D-1b) and preferably represented by Formula (D-1b).

Formula (D-1a) is as follows:

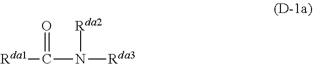

where,
R^{da1} is linear C₁₋₁₀ alkyl, branched C₃₋₁₀ alkyl or —NR^{da4}R^{da5}, preferably linear C₂₋₁₀ alkyl, branched C₃₋₁₀ alkyl or —NR^{da4}R^{da5}, more preferably amino or methyl.
R^{da2} and R^{da3} are each independently hydrogen, linear C₁₋₁₀ alkyl or branched C₃₋₁₀ alkyl, preferably hydrogen or methyl.
R^{da4} and R^{da5} are each independently hydrogen, linear C₁₋₁₀ alkyl or branched C₃₋₁₀ alkyl, preferably hydrogen or methyl.
where, when R^{da1}, R^{da2}, R^{da3}, R^{da4} and/or R^{da5} is alkyl, methylene in the alkyl may be replaced with —NH—, —S— or —O—.

Exemplified embodiments of the compound represented by Formula (D-1a) include urea, tetramethylurea, acetamide, dimethylacetamide, formamide, and N,N-dimethylformamide.

Formula (D-1 b) is as follows:

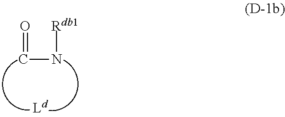

where,
R^{db1} is each independently hydrogen, linear C₁₋₁₀ alkyl or branched C₃₋₁₀ alkyl, preferably hydrogen, methyl or ethyl, and methylene in the alkyl may be replaced with —NH—, —S— or —O—, but preferably is not replaced.
L^{d} is linear or branched C₃₋₈ alkylene, linear or branched C₃₋₅ alkylene, and more preferably linear C₃₋₅ alkylene, and methylene in the alkyl may be replaced with —NH—, —S— or —O—, preferably is replaced with —NH— or not replaced, and more preferably is not replaced.

In a preferred embodiment, the ring in (D-1 b) is a 5- or 6-membered ring.

Exemplified embodiments of the compound represented by Formula (D-1 b) include ε-caprolactam, σ-valerolactam, N-methyl-2-pyrrolidone (NMP), and 1,3-dimethyl-2-imidazolidinone.

In consideration of safety and environmental properties, the component (D) is preferably selected from the group consisting of ε-caprolactam, σ-valerolactam, N-methyl-2-pyrrolidone (NMP), and 1,3-dimethyl-2-imidazolidinone.

A molecular weight of the component (D) is preferably 17 to 500 and more preferably 60 to 400.

The component (D) may be one or two or more kinds, but is preferably one or two or more kinds, and more preferably one kind.

The content of the component (D) is preferably 0.01 to 7 mass %, more preferably 0.1 to 6 mass %, and further preferably 0.7 to 3 mass %, based on the total mass of the polymer (A).

### Basic Compound (E)

The composition according to the present invention can further contain a basic compound (E). The basic compound (E) can be expected to have an effect of suppressing the environmental influence and an effect of suppressing the deactivation of the acid on the film surface due to the amine component contained in the air.

The component (E) is preferably selected from the group consisting of ammonia, C₁₋₁₆ primary aliphatic amine, C₂₋₃₂ secondary aliphatic amine, C₃₋₄₈ tertiary aliphatic amine, C₆₋₃₀ aromatic amine, and C₅₋₃₀ heterocyclic amine.

Exemplified embodiments of the component (E) include ammonia, ethylamine, n-octylamine, ethylenediamine, triethylamine, triethanolamine, tripropylamine, tributylamine, triisopropanolamine, diethylamine, tris[2-(2-methoxyethoxy)ethyl]amine, 1,8-diazabicyclo[5.4.0]undecene-7,1,5-diazabicyclo[4.3.0]nonen-5,7-methyl-1,5,7-triazabicyclo[4.4.0]deca-5-ene and 1,5,7-triazabicyclo[4.4.0]deca-5-ene.

A base dissociation constant pKb (H₂O) of the basic compound (E) is preferably −12 to 5 and more preferably 1 to 4.

A molecular weight of the component (E) is preferably 17 to 500 and more preferably 100 to 350.

The component (E) may be one or two or more kinds. The content of the component (E) is preferably 0.01 to 3 mass %, more preferably 0.05 to 1.5 mass %, and further preferably 0.08 to 0.8 mass %, based on the polymer (A).

### Solvent (F)

The composition according to the present invention can further contain a solvent (F). In the present invention, the component (D) is not included in the component (F). The component (F) is not particularly limited as long as it can dissolve each component to be mixed. The component (F) is preferably water, a hydrocarbon solvent, an ether solvent, an ester solvent, an alcohol solvent, a ketone solvent or any combination of any of these, more preferably includes propylene glycol monomethyl ether (PGME), propylene glycol monomethyl ether acetate (PGMEA), ethyl lactate, n-butyl acetate, n-butyl ether, 2-heptanone, cyclohexanone or any combination of any of these, and further preferably PGME, PGMEA or a mixture of these. When two types are mixed, the mass ratio of a first solvent to a second solvent is preferably 95:5 to 5:95 (more preferably 90:10 to 10:90; further preferably 80:20 to 20:80).

In relation to other layers or films, it is also one embodiment of the present invention that the component (F) substantially contains no water. The content of water is preferably 0.1 mass % or less, more preferably 0.01 mass % or less, and further preferably 0.001 mass % or less, based on the total mass of the component (F). It is also a preferred embodiment that the component (F) contains no water (0 mass %).

The content of the component (F) is preferably 30 to 90 mass %, more preferably 60 to 90 mass %, and further preferably 75 to 85 mass %, based on the total mass of the composition.

### Surfactant (G)

The composition according to the present invention can contain a surfactant (G). When the composition contains the component (G), the coatability can be improved. Examples of the surfactant that can be used in the present invention include (I) anionic surfactants, (II) cationic surfactants or (Ill) nonionic surfactants, and more particularly (I) alkyl sulfonate, alkyl benzene sulfonic acid and alkyl benzene sulfonate, (II) lauryl pyridinium chloride and lauryl methyl ammonium chloride and (Ill) polyoxyethylene octyl ether, polyoxyethylene lauryl ether, polyoxyethylene acetylenic glycol ether, fluorine-containing surfactants (for example, Fluorad (3M), Megaface (DIC Corporation) and Surflon (AGC Inc.)), and organic siloxane surfactants (for example, KF-53 and KP341 (Shin-Etsu Chemical Co., Ltd.)).

These surfactants may be one or two or more kinds. The content of the component (G) is preferably 0 to 20 mass %, more preferably 0.005 to 3 mass %, and further preferably 0.01 to 1 mass %, based on the total mass of the polymer (A).

### Additive (H)

The composition according to the present invention can further contain an additive (H) other than the components (A) to (G). The additive (H) is selected from at least one of the group consisting of a plasticizer, a dye, a contrast enhancer, an acid, and a substrate adhesion enhancer.

The content of the additive (H) (in the case of a plurality, the sum thereof) is preferably 0 to 20 mass %, more preferably 0 to 5 mass %, and further preferably 0 to 1 mass %, based on the total mass of the polymer (A).

It is also a preferred embodiment of the present invention that the composition according to the present invention contains no component (H).

The present invention also relates to use of the amide compound represented by Formula (D-1) or the composition according to the present invention for suppressing standing wave on a side surface of a resist pattern, improving resolution of a resist pattern, improving rectangularity, and/or improving heat resistance.

### Method for Manufacturing Resist Film

A method for manufacturing a resist film according to the present invention includes steps below:
(1) applying the above-described composition immediately above a substrate;
(2) heating the composition to form a resist film.

A method for manufacturing a resist pattern according to the present invention includes steps below:
manufacturing a resist film by the method described above;
(3) exposing the resist film; and
(4) developing the resist film.

The numbers in parentheses indicate the order of the steps. For example, when the steps (1), (2) and (3) are described, the order of the steps is as described above.

The composition according to the present invention is applied above a substrate (for example, a silicon/silicon dioxide coated substrate, a silicon nitride substrate, a silicon wafer substrate, a glass substrate, an ITO substrate, and the like) by an appropriate method. Here, in the present invention, the “above” includes the case where a film is formed immediately above a substrate and the case where a film is formed above a substrate via another layer. For example, a planarization film or resist lower layer film may be formed immediately above a substrate, and the composition according to the present invention may be applied immediately above the planarization film or resist lower layer film. In the present invention, the composition according to the present invention is preferably applied immediately above the substrate since the effect is exhibited even when a lower layer antireflection film is not formed. The application method is not particularly limited, and examples thereof include a coating method using a spinner or a coater.

After the application of the composition, a resist film is formed by heating (prebaking). The heating of the resist film is performed, for example, by a hot plate. The heating temperature is preferably 100 to 250° C., more preferably 80 to 200° C., and further preferably 90 to 180° C. The heating time is preferably 60 to 300 seconds and more preferably 90 to 180 seconds. The heating is preferably performed in an air or a nitrogen gas atmosphere.

The film thickness of the resist film varies depending on the exposure wavelength, but is preferably 0.01 to 5 μm and more preferably 0.1 to 2.5 μm.

The resist film is exposed through a predetermined mask. The wavelength of light used for exposure is not particularly limited, but a light source of 248 nm±1% or 193 nm±1% is preferably used for exposure.

After exposure, post exposure bake can be performed, as necessary. The post exposure baking temperature is preferably 80 to 150° C. and more preferably 100 to 140° C., and the heating time is preferably 60 to 300 seconds and more preferably 60 to 180 seconds. The heating is preferably performed in an air or a nitrogen gas atmosphere.

After exposure, the resist layer is developed using a developer. The developer to be used is preferably a tetramethylammonium hydroxide (TMAH) aqueous solution of 2.38 mass %. The temperature of the developer is preferably 5 to 50° C. and more preferably 25 to 40° C., and the development time is preferably 10 to 300 seconds and more preferably 30 to 90 seconds. To these developers, for example, a surfactant can also be added.

The resist layer of the exposed region is removed by development in the case of using a positive type resist composition, and the resist layer of the unexposed region is removed by development in the case of using a negative type resist composition, thereby forming a resist pattern. The resist pattern can also be further made finer, for example, using a shrink material.

In both the positive type and the negative type of the resist pattern to be formed, the influence of standing wave is reduced, and the pattern side portion has a smooth shape.

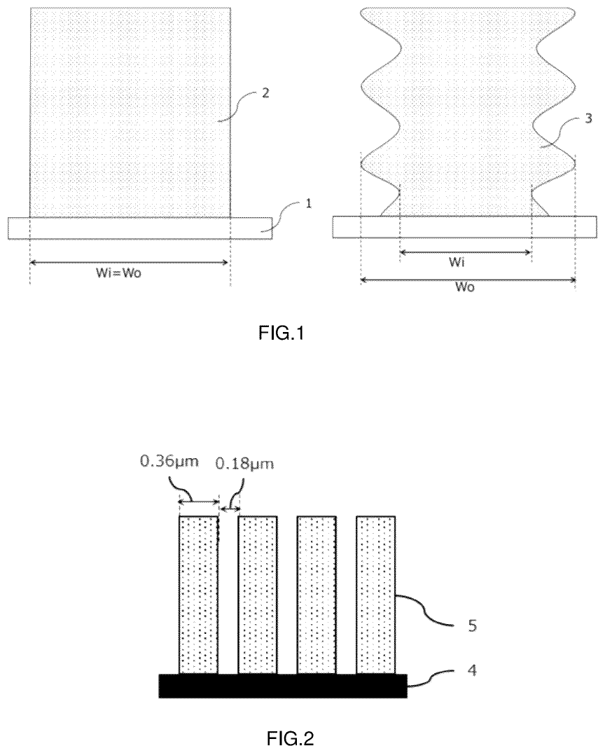

FIG. 1 is a schematic diagram of cross-sectional shapes of a resist pattern 2 not affected by standing wave and a resist pattern 3 affected by standing wave on a substrate 1. In a case where the resist pattern is affected by standing wave, when a waveform having a large amplitude is formed in the cross-section in this way, the resist top shape greatly fluctuates with a slight difference in film thickness, and the dimensional accuracy deteriorates, so that it is preferable that such an amplitude is smaller.

When widths of the resist pattern at points where the thickness of the resist pattern upward from the point where the substrate and the resist pattern are in contact with each other becomes minimum and maximum are denoted as Wi and Wo, respectively, and a ratio Sw is Wi/Wo, a case where Sw is 1 is a rectangular resist pattern, and the influence of the standing wave is suppressed as Sw approaches 1, which is preferable.

A method for manufacturing a processed substrate according to the present invention includes steps below:
manufacturing a resist pattern by the above-described method; and
(5) performing processing using the resist pattern as a mask,
in the step (5), processing is performed on a lower layer film of the resist pattern or a substrate, more preferably a substrate.

Subsequently, if necessary, the substrate is further processed to form a device. Known methods can be applied to this further processing. The method for manufacturing a device according to the present invention includes either of the above-described method, and preferably, a step of forming a wiring on the processed substrate is further comprised. Examples of the device include a semiconductor device, a liquid crystal display device, an organic EL display device, a plasma display device, and a solar cell device, and a semiconductor device is preferable.

A composite according to the present invention is obtained as an intermediate in a manufacturing stage of a processed substrate, and has at least a substrate and a resist pattern formed above the substrate, and the resist pattern contains at least a polymer A′ derived from a polymer (A) having a reactive group and an amide compound (D).

The resist pattern further contains a photoacid generator (B) and/or a quencher (C).

Preferred embodiments are listed below.

### Embodiment 1

A resist composition comprising: a polymer (A); a photoacid generator (B); and an amide compound (D), wherein the amide compound (D) is a composition represented by Formula (D-1),

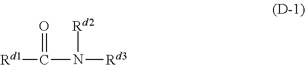

where,
R^{d1} is linear C₁₋₁₀ alkyl, branched C₃₋₁₀ alkyl or —NR^{d4}R^{d5},
R^{d2} and R^{d3} are each independently hydrogen, linear C₁₋₁₀ alkyl or branched C₃₋₁₀ alkyl,
R^{d4} and R^{d5} are each independently hydrogen, linear C₁₋₁₀ alkyl or branched C₃₋₁₀ alkyl,
where, when R^{d1} is alkyl, R^{d1} may form a ring with R^{d2}, and when R^{d1} is —NR^{d4}R^{d5}, R^{d4} or R^{d5} may form a ring with R^{d2}, and
when R^{d1}, R^{d2}, R^{d3}, R^{d4} and/or R^{d5} is alkyl, methylene (—CH₂—) in the alkyl may be replaced with —NH—, —S— or —O—.

The content of the amide compound (D) is preferably 0.01 to 7 mass % and more preferably 0.1 to 6 mass %, based on the total mass of the polymer (A).

### Embodiment 2

The composition according to Embodiment 1, wherein the amide compound (D) is represented by Formula (D-1a) or Formula (D-1b):

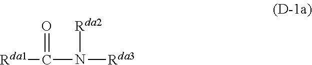

where,
R^{da1} is linear C₁₋₁₀ alkyl, branched C₃₋₁₀ alkyl or —NR^{da4}R^{da5}, preferably linear C₂₋₁₀ alkyl, branched C₃₋₁₀ alkyl or —NR^{da4}R^{Da5},
R^{da2} and R^{da3} are each independently hydrogen, linear C₁₋₁₀ alkyl or branched C₃₋₁₀ alkyl, and
R^{da4} and R^{da5} are each independently hydrogen, linear C₁₋₁₀ alkyl or branched C₃₋₁₀ alkyl,
where, when R^{da1}, R^{da2}, R^{da3}, R^{da4} and/or R^{da5} is alkyl, methylene in the alkyl may be replaced with —NH—, —S— or —O—, and

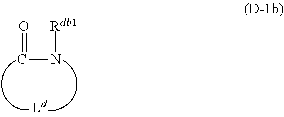

where,
R^{db1} is each independently hydrogen, linear C₁₋₁₀ alkyl or branched
C₃₋₁₀ alkyl, and methylene in the alkyl may be replaced with —NH—, —S— or —O—, and
L^{d} is linear or branched C₃₋₈ alkylene, and methylene in the alkylene may be replaced with —NH—, —S— or —O—.

Preferably, the amide compound (D) is selected from the group consisting of urea, tetramethylurea, acetamide, dimethylacetamide, formamide, N,N-dimethylformamide, ε-caprolactam, σ-valerolactam, N-methyl-2-pyrrolidone, and 1,3-dimethyl-2-imidazolidinone.

### Embodiment 3

The composition according to Embodiment 2, wherein the amide compound (D) is represented by Formula (D-1 b).

Preferably, the amide compound (D) is selected from the group consisting of ε-caprolactam, σ-valerolactam, N-methyl-2-pyrrolidone, and 1,3-dimethyl-2-imidazolidinone.

### Embodiment 4

The composition according to at least any one of Embodiments 1 to 3, wherein the polymer (A) includes at least one of repeating units represented by Formulae (A-1) and (A-2), and optionally further includes at least one of repeating units represented by Formulae (A-3) and (A-4):

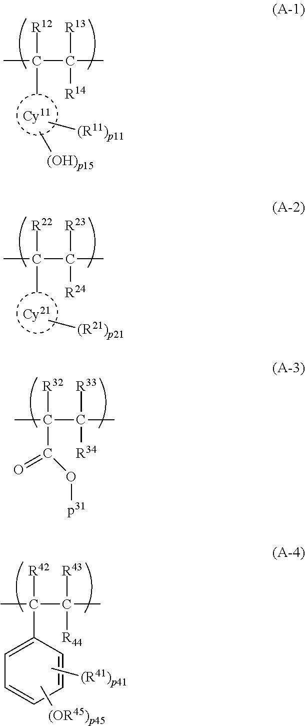

where,
C_{y}¹¹ and C_{y}²¹ are each independently aryl or heteroaryl having 5 or 6 ring atoms, preferably aryl having 5 or 6 ring atoms,
R¹¹, R²¹, R⁴¹, and R⁴⁵ are each independently C₁₋₅ alkyl (where, methylene in the alkyl may be replaced with —O—);
R¹², R¹³, R¹⁴, R²², R²³, R²⁴, R³², R³³, R³⁴, R⁴², R⁴³, and R⁴⁴ are each independently hydrogen, C₁₋₅ alkyl, C₁₋₅ alkoxy or —COOH;
p11 is 0 to 4, p15 is 1 to 2, p11+p15≤5,
p21 is 0 to 5,
p41 is 0 to 4, p45 is 1 to 2, p41+p45≤5; and
P³¹ is C₄₋₂₀ alkyl (where, some or all of alkyl may form a ring, some or all of H of the alkyl may be substituted with halogen, and methylene in the alkyl may be replaced with —O— or carbonyl),
preferably, the composition according to Embodiment 1 or 2, wherein n_{A-1}, n_{A-2}, n_{A-3} and n_{A-4}, which are the numbers of repeating units, of the repeating units (A-1), (A-2), (A-3), and (A-4) in the polymer (A) are
n_{A-1}/(n_{A-1}+n_{A-2}+n_{A-3}+n_{A-4})=0 to 100%,
n_{A-2}/(n_{A-1}+n_{A-2}+n_{A-3}+n_{A-4})=0 to 100%,
n_{A-3}/(n_{A-1}+n_{A-2}+n_{A-3}+n_{A-4})=0 to 50%, or
n_{A-4}/(n_{A-1}+n_{A-2}+n_{A-3}+n_{A-4})=0 to 50%
preferably, nₜₒₜₐₗ, which is the total number of all repeating units
included in the polymer (A), satisfies the following: (n_{A-1}+n_{A-2}+n_{A-3}+n_{A-4})/nₜₒₜₐₗ=80 to 100%, or
preferably, a mass average molecular weight Mw of the polymer (A) is 3,000 to 50,000.

### Embodiment 5

The composition according to at least any one of Embodiments 1 to 4, wherein the photoacid generator (B) is represented by Formula (B-1):
Bⁿ⁺ cation Bⁿ⁻ anion Formula (B-1)
where,
Bⁿ⁺ cation consists of at least one cation selected from the group consisting of a cation represented by Formula (BC1):

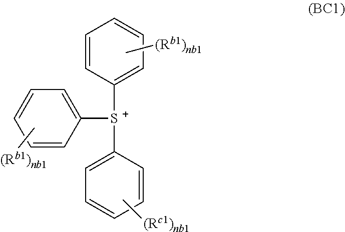

(where,
R^{b1} is each independently C₁₋₆ alkyl, C₁₋₆ alkoxy, C₆₋₁₂ aryl, C₆₋₁₂ arylthio, C₆₋₁₂ aryloxy, nitro, sulfo, carboxy, hydroxy, amino, cyano, halogen, C₁₋₆ halogen-substituted alkyl or a C₂₋₈ hydrocarbon group having an ester bond, and
nb1 is each independently 0, 1, 2 or 3),
a cation represented by Formula (BC2):

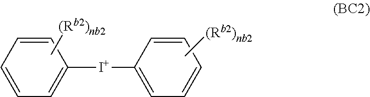

(where,
R^{b2} is each independently C₁₋₆ alkyl, C₁₋₆ alkoxy, C₆₋₁₂ aryl, nitro, sulfo, carboxy, hydroxy, amino, halogen, C₁₋₆ halogen-substituted alkyl or a C₂₋₈ hydrocarbon group having an ester bond, and
nb2 is each independently 0, 1, 2 or 3), and
a cation represented by Formula (BC3):

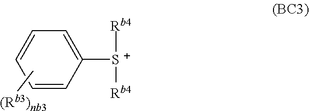

(where,
R^{b3} is each independently C₁₋₆ alkyl, C₁₋₆ alkoxy, C₆₋₁₂ aryl, nitro, sulfo, carboxy, hydroxy, amino, halogen, C₁₋₆ halogen-substituted alkyl or a C₂₋₈ hydrocarbon group having an ester bond,
R^{b4} is each independently C₁₋₆ alkyl, provided that, two R^{b4} may be linked to each other to form a ring, and
nb3 is each independently 0, 1, 2 or 3), and
is n-valent (where, n is 1 to 3) as a whole; and
Bⁿ⁻ anion consists of at least one anion selected from the group consisting of an anion represented by Formula (BA1):

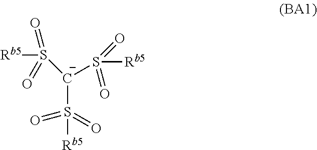

(where, R^{b5} is each independently C₁₋₆ fluorine-substituted alkyl or C₁₋₆ alkyl),
an anion represented by Formula (BA2):

R^{b6}—SO₂⁻ (BA2)
(where, R^{b6} is C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl),
an anion represented by Formula (BA3):

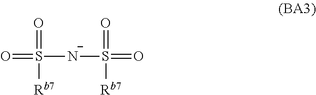

(where, R^{b7} is each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, where, two R^{b7} may be bonded to each other to form fluorine-substituted heterocyclic structure), and an anion represented by Formula (BA4):

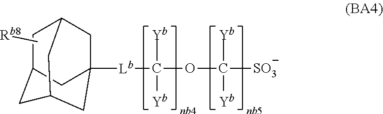

(where,
R^{b8} is hydrogen, C₁₋₆ alkyl, C₁₋₆ alkoxy or hydroxy,
L^{b} is carbonyl, oxy or carbonyloxy,
Y^{b} is each independently hydrogen or fluorine,
nb4 is an integer of 0 to 10, and
nb5 is an integer of 0 to 21), and
is n-valent as a whole.

### Embodiment 6

The composition according to at least any one of Embodiments 1 to 5, further comprising a photoreaction quencher (C) and/or a basic compound (E):
preferably, the photoreaction quencher (C) is at least one selected from the group consisting of photoreaction quenchers represented by Formula (C-1), and the basic compound (E) is at least one selected from the group consisting of ammonia, a C₁₋₁₆ primary aliphatic amine compound, a C₂₋₃₂ secondary aliphatic amine compound, a C₃₋₄₈ tertiary aliphatic amine compound, a C₆₋₃₀ aromatic amine compound, and a C₅₋₃₀ heterocyclic amine compound;
C^{m+} cation C^{m-} anion Formula (C-1)
where,
C^{m+} cation consists of at least one cation selected from the group consisting of a cation represented by Formula (CC1):

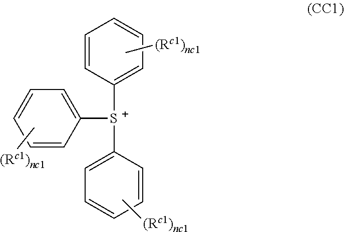

(where,
R^{d1} is each independently C₁₋₆ alkyl, C₁₋₆ alkoxy or C₆₋₁₂ aryl, and
nc1 is each independently 0, 1, 2 or 3), and
a cation represented by Formula (002):

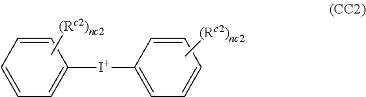

(where,
R^{c2} is each independently C₁₋₆ alkyl, C₁₋₆ alkoxy or C₆₋₁₂ aryl, and
nc2 is each independently 0, 1, 2 or 3), and
is m-valent (where, m is 1 to 3) as a whole; and
C^{m-} anion consists of at least one selected from an anion represented by Formula (CA):

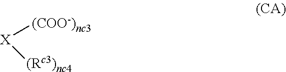

(where,
X is C₁₋₂₀ hydrocarbon or C₆₋₁₂ aryl,
R^{c3} is each independently hydroxy, carboxy, C₁₋₆ alkyl or C₆₋₁₀ aryl,
nc3 is 1, 2 or 3, and
nc4 is 0, 1 or 2), and
is m-valent as a whole.

### Embodiment 7

The composition according to at least any one of Embodiments 1 to 6, wherein the photoacid generator (B) releases an acid with an acid dissociation constant pKa (H₂O) of −20 to 1.4 by exposure, preferably, the photoreaction quencher (C) releases a weak acid with an acid dissociation constant pKa (H₂O) of 1.5 to 8 by exposure, preferably a base dissociation constant pKb (H₂O) of the basic compound (E) is −12 to 5.

### Embodiment 8

The composition according to at least any one of Embodiments 1 to 7, wherein a molecular weight of the photoacid generator (B) is 400 to 2,500 (preferably 400 to 1,500), a molecular weight of the photoreaction quencher (C) is 300 to 1,400 (preferably 300 to 1,200), a molecular weight of the amide compound (D) is 17 to 500 (preferably 60 to 400), and/or a molecular weight of the basic compound (E) is 17 to 500 (preferably 100 to 350).

### Embodiment 9

The composition according to at least any one of Embodiments 1 to 8, further comprising a solvent (F), preferably the solvent (F) being water, a hydrocarbon solvent, an ether solvent, an ester solvent, an alcohol solvent, a ketone solvent or a combination of any of these.

### Embodiment 10

The composition according to at least one of Embodiments 1 to 9, wherein a content of the polymer (A) is 10 to 60 mass % based on the total mass of the composition, and/or
a content of the photoacid generator (B) is 0.05 to 5 mass % based on the total mass of the polymer (A):
preferably, a content of the photoreaction quencher (C) is 0.01 to 3 mass % based on the total mass of the polymer (A),
preferably, a content of the basic compound (E) is 0.01 to 3 mass % based on the total mass of the polymer (A), or
preferably, a content of the solvent (F) is 30 to 90 mass % based on the total mass of the composition.

### Embodiment 11

The composition according to at least any one of Embodiments 1 to 10, further comprising a surfactant (G):
preferably, further comprising an additive (H), wherein the additive (H) is selected from at least one of the group consisting of a plasticizer, a dye, a contrast enhancer, an acid, and a substrate adhesion enhancer,
preferably, a content of the surfactant (G) is 0 to 20 mass % based on the total mass of the polymer (A), and
preferably, a content of the additive (H) is 0 to 20 mass % based on the total mass of the polymer (A).

### Embodiment 12

The composition according to at least any one of Embodiments 1 to 11, wherein the composition is a positive type chemically amplified resist composition.

### Embodiment 13

Use of the composition according to at least any one of Embodiments 1 to 12 or the amide compound represented by Formula (D-1) for suppressing standing wave on a side surface of a resist pattern, improving resolution of a resist pattern, improving rectangularity, and/or improving heat resistance.

### Embodiment 14

A method for manufacturing a resist film, comprising steps below:
(1) applying the composition according to at least any one of Embodiments 1 to 12 above a substrate; and
(2) heating the composition to form a resist film,
preferably, the heating in (2) being performed at 100 to 250° C. and/or for 60 to 300 seconds,
preferably, the heating in (2) being performed in air or a nitrogen gas atmosphere, or
preferably, a resist film having a film thickness of 0.01 to 5 μm, further preferably 0.1 to 2.5 μm being formed.

### Embodiment 15

A method for manufacturing a resist pattern, comprising steps below:
manufacturing a resist film by the method described above;
(3) exposing the resist film; preferably, a light source of 248 nm±1% or 193 nm±1% being used for exposure; and
(4) developing the resist film.

### Embodiment 16

The method according to Embodiment 15, further comprising performing post exposure bake between (3) and (4).

### Embodiment 17

A method for manufacturing a processed substrate, comprising steps below:
manufacturing a resist pattern according to the method according to Embodiment 15 or 16; and
(5) performing processing using the resist pattern as a mask,
preferably, the (5) being to perform processing on a lower layer film or a substrate (more preferably a substrate).

### Embodiment 18

A method for manufacturing a device, comprising the method according to at least any one of Embodiments 15 to 17.

### Embodiment 19

A composite comprising at least a substrate and a resist pattern formed above the substrate, the resist pattern containing at least a polymer A′ derived from a polymer (A) having a reactive group and an amide compound (D):
preferably, the resist pattern further containing a photoacid generator (B) and/or a quencher (C).

The present invention is described below with reference to various examples. The embodiment of the present invention is not limited only to these examples.

### Preparation of Composition of Example 101

PGME and EL are mixed at a mass ratio of 70:30 to obtain a mixed solvent. 100 parts by mass of polymer 1, 3.3 parts by mass of photoacid generator 1, 0.19 parts by mass of photoreaction quencher 1, 0.19 parts by mass of basic compound 1, 0.06 parts by mass of surfactant 1, and 0.5 parts by mass of ε-caprolactam as the component (D) are added to a mixed solvent, so that the solid content concentration becomes 17 mass %. The solid content concentration means the concentration of all components other than the solvent (including the mixed solvent) contained in the composition in entire composition. The resultant is stirred for 30 minutes at room temperature. It is visually checked that the added components are dissolved. The resultant is filtered through a 0.05 μm filter. Thereby, a composition of Example 1 is obtained.
Polymer 1: Hydroxystyrene:styrene:t-butyl acrylate copolymer, molar ratio 6:2:2, Mw: 12,000, the above ratio indicates the constituent ratio of each repeating unit.

The same applies hereinafter.

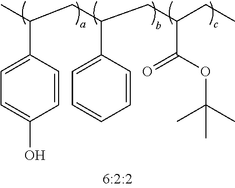

Photoacid generator 1

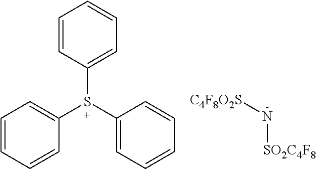

Photoreaction quencher 1

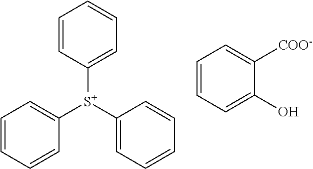

Basic compound 1: tris[2-(2-methoxyethoxy)ethyl]amine
Surfactant 1: KF-53 (Shin-Etsu Chemical Co., Ltd.)

### Preparation of Compositions of Examples 102 to 107 and Comparative Examples 101 to 108

Compositions of Examples 102 to 107 and Comparative Examples 101 to 108 are obtained in the same manner as in “Preparation of composition of Example 101”, except that ε-caprolactam of Example 1 is changed to the compounds and blending amounts shown in Tables 1 and 2. The unit of the numerical value of the composition in the table is part(s) by mass.

TABLE 1

| | | Examples | | | | | | |
|---|---|---|---|---|---|---|---|---|
| | | 101 | 102 | 103 | 104 | 105 | 106 | 107 |
| (D) | ε-caprolactam | 0.5 | 1 | 5 | — | — | — | — |
| | N-methyl-2- | — | — | — | 1 | — | — | — |
| | pyrrolidone | | | | | | | |
| | urea | — | — | — | — | 1 | — | — |
| | 1,3-dimethyl-2- | — | — | — | — | — | 1 | — |
| | imidazolidinone | | | | | | | |
| | σ-valerolactam | — | — | — | — | — | — | 1 |

| | | | | | | | |
|---|---|---|---|---|---|---|---|
| diacetamide | — | — | — | — | — | — | — |
| acetanilide | — | — | — | — | — | — | — |
| methansulfonamide | — | — | — | — | — | — | — |
| γ-buthyrolactone | — | — | — | — | — | — | — |
| dipropylene glycol | — | — | — | — | — | — | — |
| methyl ether | | | | | | | |
| Sw | 0.95 | 0.99 | 0.99 | 0.96 | 0.97 | 0.95 | 0.97 |
| Standing wave | B | A | A | A | A | A | A |
| Resolution (μm) | 0.16 | 0.17 | 0.17 | 0.17 | 0.17 | 0.17 | 0.17 |

TABLE 2

| | | Comparative Examples | | | | | | | |
|---|---|---|---|---|---|---|---|---|---|
| | | 101 | 102 | 103 | 104 | 105 | 106 | 107 | 108 |
| (D) | ε-caprolactam | — | 10 | — | — | — | — | — | — |
| | N-methyl-2- | — | — | — | — | — | — | — | — |
| | pyrrolidone | | | | | | | | |
| | urea | — | — | — | — | — | — | — | — |
| | 1,3-dimethyl-2- | — | — | — | — | — | — | — | — |
| | imidazolidinone | | | | | | | | |
| | σ-valerolactam | — | — | — | — | — | — | — | — |

| | | | | | | | | |
|---|---|---|---|---|---|---|---|---|
| diacetamide | — | — | 1 | — | — | — | — | — |
| acetanilide | — | — | — | 1 | — | — | — | — |
| methansulfonamide | — | — | — | — | 30 | — | — | — |
| γ-buthyrolactone | — | — | — | — | — | 30 | — | — |
| dipropylene glycol | — | — | — | — | — | — | 30 | — |
| methyl ether | | | | | | | | |
| Su | 0.77 | — | 0.74 | 0.78 | 0.78 | 0.74 | 0.66 | 0.80 |
| Standing wave | D | — | D | D | D | D | D | D |
| Resolution (μm) | 0.18 | 0.18 | 0.18 | 0.18 | 0.18 | 0.18 | 0.18 | 0.18 |

### Formation of Resist Pattern

Using a coater developer Mark 8 (Tokyo Electron Ltd.), each composition is dropped onto an 8 inch Si wafer and spin-coating is performed. This wafer is heated at 130° C. for 140 seconds using a hot plate under atmospheric conditions to form a resist film. The film thickness of the resist film at this point is 1.5 μm when measured by an optical interference type film thickness measuring device M-1210 (SCREEN).

This resist layer is exposed using a KrF stepper FPA3000-EX5 (Canon). The exposed wafer is heated (PEB) at 120° C. for 90 seconds using a hot plate under atmospheric conditions. Thereafter, this resist layer is puddle-developed with a 2.38 mass % TMAH aqueous solution for 60 seconds, washed with water, and spin-dried at 1,000 rpm. Thereby, a trench pattern with a line width of 0.36 μm and a space width of 0.18 μm is formed. The line width and the space width are values measured at the bottom portion of the pattern.

FIG. 2 schematically illustrates this pattern shape, and a resist pattern 5 is formed on a substrate 4. The exposure amount with which the trench pattern having a line width of 0.36 μm and a space width of 0.18 μm is formed is defined as an optimum exposure amount, and the following evaluation is performed at this optimum exposure amount.

In Comparative Example 102, a resist pattern is not formed.

### Evaluation of Cross-Sectional Shape

A section of the substrate formed in “Formation of resist pattern” is formed and the vertical cross-section is observed with a scanning type electron microscope (SEM). Upward from the point where the substrate and the resist pattern are in contact with each other, the widths of the resist pattern at points where the thickness of the resist pattern becomes minimum and maximum are denoted as Wi and Wo, respectively. These Wi and Wo are measured, and the ratio Sw=Wi/Wo is calculated.

The value of Sw is evaluated according to the following criteria.

The obtained results are described in Tables 1 and 2.
A: Sw is larger than 0.95.
B: Sw is larger than 0.9 and 0.95 or less.
C: Sw is larger than 0.8 and 0.9 or less.
D: Sw is 0.8 or less.

### Evaluation of Resolution

A resist pattern is formed in the same manner as in “Formation of resist pattern”, except that exposure is performed using a mask pattern having a space size of 0.50 to 0.08 μm with the optimum exposure amount described in “Formation of resist pattern”. The minimum dimension in which the resist pattern could be formed is defined as resolution (nm), and the resolution is evaluated according to the following criteria. The evaluation results are described in Tables 1 and 2.

### EXPLANATION OF SYMBOLS

1 Substrate
2 Resist pattern not affected by standing wave
3 Resist pattern affected by standing wave
4 Substrate
5 Resist pattern

1. A resist composition comprising:
a polymer (A);
a photoacid generator (B); and
an amide compound (D),
wherein the amide compound (D) is a composition represented by Formula (D-1), 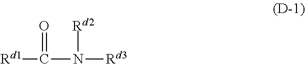
where,
R^{d1} is linear C₁₋₁₀ alkyl, branched C₃₋₁₀ alkyl or —NR^{d4}R^{d5},
R^{d2} and R^{d3} are each independently hydrogen, linear C₁₋₁₀ alkyl or branched C₃₋₁₀ alkyl, and
R^{d4} and R^{d5} are each independently hydrogen, linear C₁₋₁₀ alkyl or branched C₃₋₁₀ alkyl, and
where, when R^{d1} is alkyl, R^{d1} may form a ring with R^{d2}, and when R^{d1} is —NR^{d4}R^{d5}, R^{d4} or R^{d5} may form a ring with R^{d2}, and
when R^{d1}, R^{d2}, R^{d3}, R^{d4} and/or R^{d5} is alkyl, methylene (—CH₂—) in the alkyl may be replaced with —NH—, —S— or —O—.

2. The composition according to claim 1, wherein a content of the amide compound (D) is 0.01 to 7 mass % based on a total mass of the polymer (A).

3. The composition according to claim 1, wherein the amide compound (D) is represented by Formula (D-1a) or Formula (D-1 b): 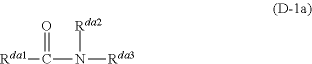
where,
R^{da1} is linear C₁₋₁₀ alkyl, branched C₃₋₁₀ alkyl or —NR^{da4}R^{da5},
R^{da2} and R^{da3} are each independently hydrogen, linear C₁₋₁₀ alkyl or branched C₃₋₁₀ alkyl, and
R^{da4} and R^{da5} are each independently hydrogen, linear C₁₋₁₀ alkyl or branched C₃₋₁₀ alkyl,
where, when R^{da1}, R^{da2}, R^{da3}, R^{da4} and/or R^{da5} is alkyl, methylene in the alkyl may be replaced with —NH—, —S— or —O—, and 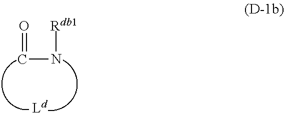
where,
R^{db1} is each independently hydrogen, linear C₁₋₁₀ alkyl or branched C₃₋₁₀ alkyl, and methylene in the alkyl may be replaced with —NH—, —S— or —O—, and
L^{d} is linear or branched C₃₋₈ alkylene, and methylene in the alkylene may be replaced with —NH—, —S— or —O—.

4. The composition according to claim 3, wherein the amide compound (D) is represented by Formula (D-1 b).

5. The composition according to claim 1, wherein the polymer (A) comprises at least one of repeating units represented by Formulae (A-1) and (A-2), and optionally further comprises at least one of repeating units represented by Formulae (A-3) and (A-4): 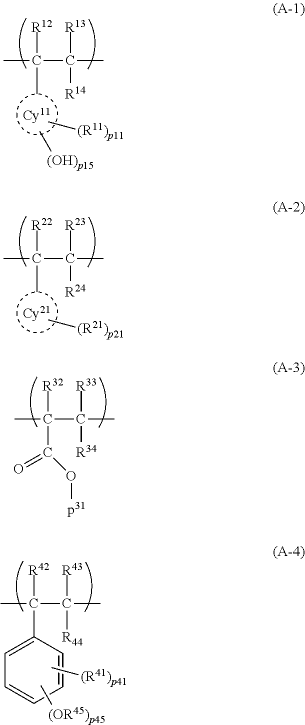
where,
C_{y}¹¹ and C_{y}²¹ are each independently aryl or heteroaryl having 5 or 6 ring atoms,
R¹¹, R²¹, R⁴¹, and R⁴⁵ are each independently C₁₋₅ alkyl (where, methylene in the alkyl may be replaced with —O—);
R¹², R¹³, R¹⁴, R²², R²³, R²⁴, R³², R³³, R³⁴, R⁴², R⁴³, and R⁴⁴ are each independently hydrogen, C₁₋₅ alkyl, C₁₋₅ alkoxy or —COOH;
p11 is 0 to 4, p15 is 1 to 2, p11+p15≤5,
p21 is 0 to 5,
p41 is 0 to 4, p45 is 1 to 2, p41+p45≤5; and
P³¹ is C₄₋₂₀ alkyl (where, some or all of alkyl may form a ring, some or all of H of the alkyl may be substituted with halogen, and methylene in the alkyl may be replaced with —O— or carbonyl).

6. The composition according to claim 5, wherein n_{A-1}, n_{A-2}, n_{A-3}, and n_{A-4}, which are the numbers of repeating units, of the repeating units (A-1), (A-2), (A-3), and (A-4) in the polymer (A) are
n_{A-1}/(n_{A-1}+n_{A-2}+n_{A-3}+n_{A-4})=0 to 100%,
n_{A-2}/(n_{A-1}+n_{A-2}+n_{A-3}+n_{A-4})=0 to 100%,
n_{A-3}/(n_{A-1}+n_{A-2}+n_{A-3}+n_{A-4})=0 to 50%, or
n_{A-4}/(n_{A-1}+n_{A-2}+n_{A-3}+n_{A-4})=0 to 50%.

7. The composition according to claim 6, wherein nₜₒₜₐₗ, which is the total number of all repeating units included in the polymer (A), satisfies the following:
(n_{A-1}+n_{A-2}+n_{A-3}+n_{A-4})/nₜₒₜₐₗ=80 to 100%,
and optionally, wherein a mass average molecular weight Mw of the polymer (A) is 3,000 to 50,000.

8. The composition according to claim 1, wherein the photoacid generator (B) is represented by Formula (B-1):
Bⁿ⁺ cation Bⁿ⁻ anion Formula (B-1)
where,
Bⁿ⁺ cation consists of at least one cation selected from the group consisting of a cation represented by Formula (BC1): 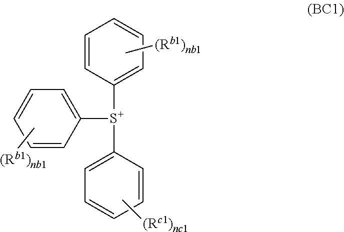
(where,
R^{b1} is each independently C₁₋₆ alkyl, C₁₋₆ alkoxy, C₆₋₁₂ aryl, C₆₋₁₂ arylthio, C₆₋₁₂ aryloxy, nitro, sulfo, carboxy, hydroxy, amino, cyano, halogen, C₁₋₆ halogen-substituted alkyl or a C₂₋₈ hydrocarbon group having an ester bond, and
nb1 is each independently 0, 1, 2 or 3),
a cation represented by Formula (BC2): 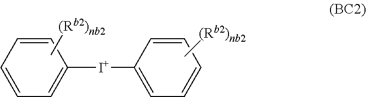
(where,
R^{b2} is each independently C₁₋₆ alkyl, C₁₋₆ alkoxy, C₆₋₁₂ aryl, nitro, sulfo, carboxy, hydroxy, amino, halogen, C₁₋₆ halogen-substituted alkyl or a C₂₋₈ hydrocarbon group having an ester bond, and
nb2 is each independently 0, 1, 2 or 3), and
a cation represented by Formula (BC3): 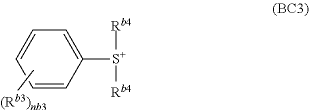
(where,
R^{b3} is each independently C₁₋₆ alkyl, C₁₋₆ alkoxy, C₆₋₁₂ aryl, nitro, sulfo, carboxy, hydroxy, amino, halogen, C₁₋₆ halogen-substituted alkyl or a C₂₋₈ hydrocarbon group having an ester bond,
R^{b4} is each independently C₁₋₆ alkyl, provided that, two R^{b4} may be linked to each other to form a ring, and
nb3 is each independently 0, 1, 2 or 3), and
is n-valent (where, n is 1 to 3) as a whole; and
Bⁿ⁻ anion consists of at least one anion selected from the group consisting of an anion represented by Formula (BA1): 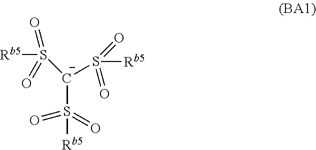
(where, R^{b5} is each independently C₁₋₆ fluorine-substituted alkyl or C₁₋₆ alkyl),
an anion represented by Formula (BA2):
R^{b6}—SO₂⁻ (BA2)
(where, R^{b6} is C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl),
an anion represented by Formula (BA3): 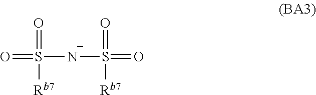
(where, R^{b7} is each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, where, two R^{b7} may be bonded to each other to form fluorine-substituted heterocyclic structure), and
an anion represented by Formula (BA4): 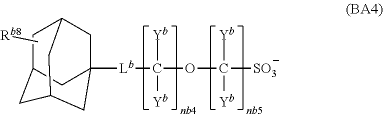
(where,
R^{b8} is hydrogen, C₁₋₆ alkyl, C₁₋₆ alkoxy or hydroxy,
L^{b} is carbonyl, oxy or carbonyloxy,
Y^{b} is each independently hydrogen or fluorine,
nb4 is an integer of 0 to 10, and
nb5 is an integer of 0 to 21), and
is n-valent as a whole.

9. The composition according to claim 1, further comprising a photoreaction quencher (C) and/or a basic compound (E).

10. The composition of claim 9, wherein the photoreaction quencher (C) is at least one selected from the group consisting of photoreaction quenchers represented by Formula (C-1), and the basic compound (E) is at least one selected from the group consisting of ammonia, a C₁₋₁₆ primary aliphatic amine compound, a C₂₋₃₂ secondary aliphatic amine compound, a C₃₋₄₈ tertiary aliphatic amine compound, a C₆₋₃₀ aromatic amine compound, and a C₅₋₃₀ heterocyclic amine compound;
C^{m+} cation C^{m-} anion Formula (C-1)
where,
C^{m+} cation consists of at least one cation selected from the group consisting of:
a cation represented by Formula (CC1): 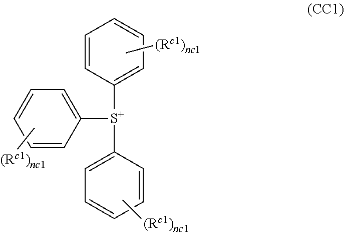
(where,
R^{c1} is each independently C₁₋₆ alkyl, C₁₋₆ alkoxy or C₆₋₁₂ aryl, and
nc1 is each independently 0, 1, 2 or 3), and
a cation represented by Formula (CC2): 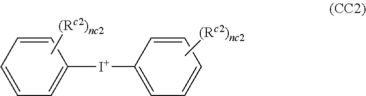
(where,
R^{c2} is each independently C₁₋₆ alkyl, C₁₋₆ alkoxy or C₆₋₁₂ aryl, and
nc2 is each independently 0, 1, 2 or 3), and
is m-valent (where, m is 1 to 3) as a whole; and
C^{m-} anion consists of at least one selected from an anion represented by Formula (CA): 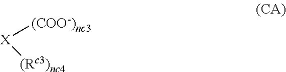
(where,
X is C₁₋₂₀ hydrocarbon or C₆₋₁₂ aryl,
R^{c3} is each independently hydroxy, carboxy, C₁₋₆ alkyl or C₆₋₁₀ aryl,
nc3 is 1, 2 or 3, and
nc4 is 0, 1 or 2), and
is m-valent as a whole.

11. The composition according to claim 9, wherein the photoacid generator (B) releases an acid with an acid dissociation constant pKa (H₂O) of −20 to 1.4 by exposure, and optionally, wherein the photoreaction quencher (C) releases a weak acid with an acid dissociation constant pKa (H₂O) of 1.5 to 8 by exposure, and further optionally, wherein a base dissociation constant pKb (H₂O) of the basic compound (E) is −12 to 5.

12. The composition according to claim 9, wherein a molecular weight of the photoacid generator (B) is 400 to 2,500, a molecular weight of the photoreaction quencher (C) is 300 to 1,400, a molecular weight of the amide compound (D) is 17 to 500, and/or a molecular weight of the basic compound (E) is 17 to 500.

13. The composition according to claim 1, wherein the composition is a positive type chemically amplified resist composition.

14. A method for manufacturing a resist film, comprising steps below:
(1) applying the composition according to claim 1 above a substrate;
and (2) heating the composition to form a resist film.

15. The method of claim 14, wherein the heating in (2) is performed at 100 to 250° C. for 60 to 300 seconds, and optionally, wherein the heating in (2) is performed in air or a nitrogen gas atmosphere, and further optionally, wherein a resist film having a film thickness of 0.01 to 5 μm.

16. A method for manufacturing a resist pattern, comprising steps below:
manufacturing a resist film by the method according to claim 14;
(3) exposing the resist film; and
(4) developing the resist film.

17. The method according to claim 16, further comprising performing post exposure bake between (3) and (4).

18. A method for manufacturing a processed substrate, comprising steps below:
manufacturing a resist pattern according to the method according to claim 16; and
(5) performing processing using the resist pattern as a mask.

19. A method for manufacturing a device, comprising the method according to claim 18.

20. A composite comprising at least a substrate and a resist pattern formed above the substrate, the resist pattern containing at least a polymer A′ derived from a polymer (A) having a reactive group and an amide compound (D), and optionally, the resist pattern further containing a photoacid generator (B) and/or a quencher (C).
